(19) United States
(12) Patent Application Publication
(10) Pub. No.: US 2012/0099614 A1
(43) Pub. Date: Apr. 26, 2012

(54) SEMICONDUCTOR LASER DEVICE AND MANUFACTURING METHOD THEREOF

(75) Inventors: Tomohiro YAMAZAKI, Okayama (JP); Akiyoshi KUDO, Hyogo (JP); Kouji MAKITA, Hyogo (JP)

(73) Assignee: PANASONIC CORPORATION, Osaka (JP)

(21) Appl. No.: 13/275,653

(22) Filed: Oct. 18, 2011

(30) Foreign Application Priority Data
Oct. 22, 2010 (JP) 2010-238017

(51) Int. Cl. H01S 5/026

(52) U.S. Cl. 372/46.01

(57) ABSTRACT

A semiconductor laser device of the present invention includes: a substrate; a cladding layer of a first conductivity type formed above one of surfaces of the substrate; an active layer formed above the cladding layer of the first conductivity type; a cladding layer of a second conductivity type formed above the active layer, and having a ridge and a planar portion; a dielectric film formed on a lower portion of a side surface of the ridge and on the planar portion; a first electrode formed on an other one of the surfaces of the substrate; a second electrode formed above the ridge; a third electrode formed over the second electrode and the dielectric film to cover the ridge and the planar portion; and a cavity provided between the third electrode and at least a part of the side surface of the ridge.

### BACKGROUND OF THE INVENTION

(1) Field of the Invention

The present invention relates to semiconductor laser devices and methods of manufacturing the semiconductor laser devices and, in particular, to a nitride semiconductor laser device made of nitride semiconductor and a method of manufacturing the nitride semiconductor laser device.

(2) Description of the Related Art

Recently, light-emitting semiconductor devices made of nitride semiconductor have been rapidly available as light emitting diodes (LEDs) and laser diodes (LDs). In particular, GaN semiconductor laser diodes made of gallium nitride (GaN) are gaining an important industrial position as a key device for an optical pickup device in a high-density and high-speed-recording optical disc system.

A typical GaN semiconductor laser diode employs InGaN as an active layer on a GaN substrate, and AlGaN as a cladding layer formed above and below the active layer. Here, compressive strain and tensile strain respectively develop on the active layer and the cladding layer. Consider the case of a semiconductor laser device formed in a ridge structure; that is, a stripe-like ridge is provided to a p-type cladding layer above the active layer. Here, even greater compressive strain develops on the active layer directly below the ridge in a direction perpendicular to a resonating direction of a laser resonator. This compressive strain occurs as a reaction of the tensile strain developed on the cladding layer. The use of such a phenomenon provides a high-performance light-emitting semiconductor device having a low threshold current in a simple structure (See Patent Reference 1: Japanese Unexamined Patent Application Publication No. 08-255932).

Unfortunately, the strain developed on the active layer directly below the ridge negatively affects the lifetime characteristics of the light-emitting semiconductor device under a high-power operation. The strain developed on the active layer directly below the ridge is caused by the stress of a p-side electrode and of a dielectric film working as a current block layer provided above the active layer.

Most of major metals used for the p-side electrode of the GaN semiconductor laser diode, including Ni (nickel) and Pd (palladium) used for an ohmic electrode, have tensile stress. Thus, when the p-side electrode makes contact with a side of the ridge, the contact acts to increase the compressive strain to be developed on the active layer directly below the ridge. In addition, the use of a metal having a high thermal expansion coefficient further increases the compressive strain to be developed on the active layer due to a temperature increase, such as self-heating. Table 1 shows thermal expansion coefficients of the major metals used for the p-side electrode.

TABLE 1

| | Thermal Expansion Coefficient |
|---|---|
| Metal | (×10⁻⁶/° C.) |
| Ni | 12.8 |
| Pd | 11.6 |
| Pt | 9.1 |
| Ti | 8.4 |
| Cr | 6.8 |
| Au | 14.1 |
| Mo | 5.2 |
| Ag | 19.1 |

As shown in Table 1, Ni and Pd to be used for the ohmic electrode have high thermal expansion coefficients over 10×10⁻⁶ (° C.). Thus, it is inevitable for the active layer to receive a greater compressive strain due to a temperature increase.

Here, Patent Reference 2 (Japanese Unexamined Patent Application Publication No. 2007-288149) and Patent Reference 3 (Japanese Unexamined Patent Application Publication No. 03-142985) disclose, as examples, methods for reducing a stress on a semiconductor multilayer in a semiconductor laser diode.

Patent Reference 2 discloses that, in a GaN semiconductor laser diode, cavities are created between both sides of the ridge of the p-type semiconductor layer and insulating protective films so as to reduce the stress imposed on the interfaces between the ridge and the insulating protective films having contact with the ridge.

In addition, Patent Reference 3 discloses that, in a semiconductor laser diode, the strain on an electrode can be reduced when (i) guides are created on both sides of the mesa portion (ridge) of the cladding layer, (ii) no electrode is formed on the sides of the mesa portion (ridge), and (iii) the electrode is formed apart from the light-emitting region.

The Patent References 2 and 3, however, show structures such that the cavities are formed on the entire sides of the ridge of the cladding layer, and on planar portions (portions with no ridge formed on the cladding layer). When the semiconductor laser diodes operate under a high-power operation, this structure causes a problem of discouraging heat dissipation directly below the ridge where the highest heat is generated.

### SUMMARY OF THE INVENTION

The present invention is conceived in view of the above problem and has an object to provide (i) a nitride semiconductor laser device capable of reducing compressive strain developed on the active layer directly below the ridge even with the use of an ohmic electrode having a high thermal expansion coefficient while securing the heat dissipation capacity of the ridge, and (ii) a method for manufacturing the nitride semiconductor laser device.

In order to achieve the above object, a semiconductor laser device according to an aspect of the present invention includes: a substrate; a cladding layer of a first conductivity type formed above one of surfaces of the substrate; an active layer formed above the cladding layer of the first conductivity type; a cladding layer of a second conductivity type formed above the active layer, and having a ridge and a planar portion provided on a surface of the cladding layer of the second conductivity type; a dielectric film formed on a lower portion of a side surface of the ridge and on the planar portion; a first electrode formed on an other one of the surfaces of the substrate; a second electrode formed above the ridge; a third electrode formed over the second electrode and the dielectric film to cover the ridge and the planar portion; and a cavity provided between the third electrode and at least a part of the side surface of the ridge.

According to the aspect, the lower portion of the side surface of the ridge on the cladding layer of the second conductivity type is connected to the third electrode via the dielectric film. This structure allows efficient heat dissipation directly below the ridge where the highest heat is generated under a high-power operation. Furthermore, according to the aspect, the cavity keeps the third electrode from a part of the cladding layer of the second conductivity type. This structure makes it possible to reduce compressive strain developed on the active layer, even though the second electrode is made of an electrode material having a high thermal expansion coefficient.

Preferably, the semiconductor laser device in another aspect of the present invention includes a contact layer of the second conductivity type formed between the second electrode and the ridge of the cladding layer of the second conductivity type, wherein the cavity is provided between the third electrode and the side surface of the contact layer of the second conductivity type.

Preferably, the semiconductor laser device in another aspect of the present invention is made of an III-V group nitride semiconductor material in an InAlGaN series.

Preferably, in the semiconductor laser device in another aspect of the present invention, the cladding layer of the second conductivity type is made of AlGaN.

Preferably, in the semiconductor laser device in another aspect of the present invention, the active layer is made of InGaN.

Preferably, in the semiconductor laser device in another aspect of the present invention, the second electrode is one of (i) a single layer film made of Pd or Ni and (ii) a multilayer film made of Pd and Ni.

Preferably, in the semiconductor laser device in another aspect of the present invention, the third electrode is a multilayer film made of metals other than Pd and Ni, and at least an outermost metal layer of the multilayer film is formed continuously above the ridge through the dielectric film.

Preferably, in the semiconductor laser device in another aspect of the present invention, the dielectric film is one of (i) a single layer film, such as a SiO₂ film, an AlN film, or an Al₂O₃ film and (ii) a multilayer film including at least two of the SiO₂ film, the AlN film, and the an Al₂O₃ film.

Preferably, in the semiconductor laser device in another aspect of the present invention, the second electrode is wider than the ridge.

A method for manufacturing a semiconductor laser device according to an aspect of the present invention includes: sequentially forming, on a substrate, a cladding layer of a first conductivity type, an active layer, a cladding layer of a second conductivity type, and a contact layer of the second conductivity type; forming a ridge portion by etching the cladding layer of the second conductivity type and the contact layer of the second conductivity type; forming a dielectric film to cover the ridge portion; etching the dielectric film to selectively expose a side surface of the ridge portion; forming a second electrode above the ridge portion; and forming a third electrode over the second electrode, wherein, in the forming the second electrode, the second electrode is (i) formed by a rotating film-forming technique on the contact layer of the second conductivity type but not on the exposed side surface of the ridge portion, and (ii) formed wider than a top face of the contact layer of the second conductivity type, and, in the forming the third electrode, the third electrode is formed by a revolving film-forming technique such that a cavity is provided between the third electrode and the exposed side surface of the ridge portion.

A semiconductor laser device and a method of manufacturing the semiconductor laser device of the present invention successfully reduce compressive strain developed on the active layer even though the second electrode is made of an electrode material having a high thermal expansion coefficient, as well as secure the heat dissipation capacity of the ridge. These features can improve lifetime characteristics of the semiconductor laser device.

Further Information about Technical Background to this Application

The disclosure of Japanese Patent Application No. 2010-238017 filed on Oct. 22, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 shows a cross-sectional view of a semiconductor laser device according to an embodiment of the present invention;

FIG. 2 shows cross-sectional views of each of manufacturing schemes in a method for manufacturing the semiconductor laser device according to the embodiment of the present invention;

FIG. 3A shows a cross-sectional view of an enlarged substantial part of the semiconductor laser device according to the embodiment of the present invention;

FIG. 3B depicts a relationship between the time change and the operating voltage change observed in the semiconductor laser device according to the embodiment of the present invention;

FIG. 4A shows a cross-sectional view of an enlarged substantial part of a semiconductor laser device according to a comparative example; and

FIG. 4B depicts a relationship between the time change and the operating voltage change observed in the semiconductor laser device according to the comparative example.

### DESCRIPTION OF THE PREFERRED EMBODIMENT

With reference to the drawings, described hereinafter are a semiconductor laser device according to an embodiment of the present invention and a method of manufacturing the semiconductor laser device. It is noted that the embodiment shows the case where the semiconductor laser device and its manufacturing method are applied to a GaN semiconductor laser diode.

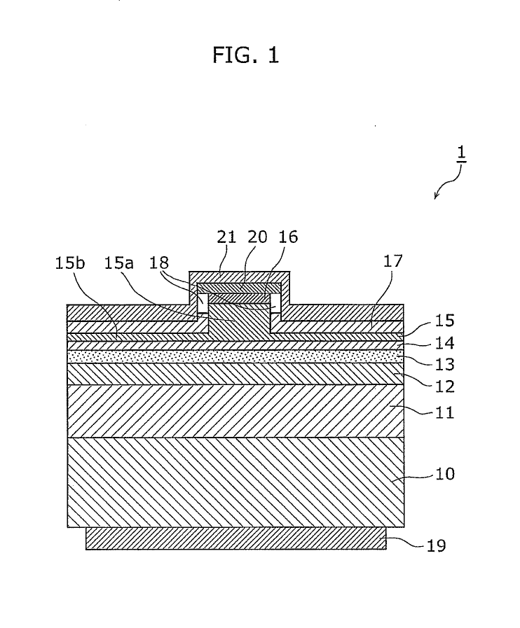

Described first with FIG. 1 is the semiconductor laser device according to the embodiment of the present invention. FIG. 1 is a cross-sectional view (a cross-sectional view perpendicular to a resonating direction of a laser resonator) of the semiconductor laser device according to the embodiment of the present invention.

A semiconductor laser device 1 according to the embodiment of the present invention is a GaN semiconductor laser diode made of a III-V group nitride semiconductor material in an InAlGaN series. As shown in FIG. 1, the semiconductor laser device 1 includes: a semiconductor multilayer, a dielectric film 17, a cavity 18, a first electrode 19, a second electrode 20, and a third electrode 21. The semiconductor multilayer includes: a substrate 10, a cladding layer of a first conductivity type 11, a light guide layer of a first conductivity type 12, an active layer 13, a light guide layer of a second conductivity type 14, a cladding layer of a second conductivity type 15, and a contact layer of a second conductivity type 16. Detailed hereinafter is each of constitutional elements of the semiconductor laser device 1.

The substrate 10 is a semiconductor substrate having one surface and another surface opposing the one surface. The substrate 10 may be an n-type GaN substrate, for example.

The cladding layer of the first conductivity type 11 is made of n-type AlₓGa₁₋ₓN of a first conductivity type, and formed on one of the surfaces of the substrate 10. In the embodiment, the cladding layer of the first conductivity type 11 is formed of an n-type Al_{0.03}Ga₁₋ₓN layer having a film thickness of 2.5 μm (x=0.03).

The light guide layer of the first conductivity type 12 is made of n-type nitride semiconductor and formed on the cladding layer of the first conductivity type 11. In the embodiment, the light guide layer of the first conductivity type 12 is made of n-type GaN having a film thickness of 0.1 μm.

The active layer 13 is a quantum well active layer formed of a barrier layer made of In_{y}Ga_{1-y}N and a well layer made of InₛGa₁₋ₛN, and is formed on The light guide layer of the first conductivity type 12. In the embodiment, the active layer 13 is a quantum well active layer formed of a barrier layer made of In_{0.08}Ga_{9.92}N (y=0.08) and a well layer made of In_{0.03}Ga_{9.97}N (s=0.03).

The light guide layer of the second conductivity type 14 is made of p-type nitride semiconductor of a second conductivity type, not the first conductivity type, and formed on the active layer 13. In the embodiment, the light guide layer of the second conductivity type 14 is made of n-type GaN having a film thickness of 0.1 μm.

The cladding layer of the second conductivity type 15 is made of p-type AlₜGa₁₋ₜN and formed on the light guide layer of the second conductivity type 14. In the embodiment, the cladding layer of the second conductivity type 15 is made of p-type Al_{0.03}Ga_{9.97}N having a film thickness of 0.5 μm (t=0.03).

On the surface of the cladding layer of the second conductivity type 15, there are a ridge 15a and a planar portion 15b. The ridge 15a is projected in cross-section, and formed in a stripe-like shape, extending along a resonating direction of the laser resonator. The width of the stripe of the ridge 15a may be approximately 1.4 μm, for example. The planar portion 15b is a region having no ridge 15a formed on the cladding layer of the second conductivity type 15. The planar portion 15b is a surface formed on both sides of the ridge 15a. Thus, on the cladding layer of the second conductivity type 15, the film thickness of the planar portion 15b is made to be thinner than that of the ridge 15a (the height of the ridge).

The contact layer of the second conductivity type 16 is made of p-type nitride semiconductor, and formed on the ridge 15a of the cladding layer of the second conductivity type 15. In the embodiment, the contact layer of the second conductivity type 16 is formed to have the same width as the ridge 15a has, and is made of p⁺-type GaN having a film thickness of 50 nm.

In the embodiment, the contact layer of the second conductivity type 16 and a part of the cladding layer of the second conductivity type 15 are formed in a ridge stripe-like shape, extending along the resonating direction of the laser resonator. The contact layer of the second conductivity type 16 forms a ridge portion with the ridge 15a of the cladding layer of the second conductivity type 15. In other words, the semiconductor laser device 1 according to the embodiment has the ridge portion formed of the ridge 15a of the cladding layer of the second conductivity type 15 and the contact layer of the second conductivity type 16.

Acting as a current block layer, the dielectric film 17 is formed on the cladding layer of the second conductivity type 15. Specifically, the dielectric film 17 is formed on the planar portion 15b and a part of the side portion (side surface) of the ridge 15a. The dielectric film 17 is continuously formed over the planar portion 15b through the ridge 15a.

In the embodiment, the dielectric film 17 is formed on a lower portion (base portion) of the side surface of the ridge 15a; however, the dielectric film 17 is not formed either on an upper portion of the side surface of the ridge 15a or the side surface of the contact layer of the second conductivity type 16. Hence, the upper portion of the side surface of the 15a and the side surface of the contact layer of the second conductivity type 16 are exposed such that a part of the ridge portion is exposed to the dielectric film 17. Accordingly, the upper portion of the side surface of the ridge 15a and the contact layer of the second conductivity type 16 do not make contact with the dielectric film 17.

The region (height of the dielectric film), where the dielectric film 17 is formed in contact with the side surface of the ridge portion, is defined as follows: The top of the region is not so high that the top does not reach the side surface of the contact layer of the second conductivity type 16, and the bottom of the region is not so low that the planar portion of the ridge is not exposed. Preferably, the region is approximately half as high as the ridge 15a. The dielectric film 17 may be formed within the range.

The dielectric film 17 may be (i) a single layer film, such as a SiO₂ film, an AlN film, or an Al₂o₃ film, or (ii) a multilayer film including at least two selected kinds of films out of the three and formed of layered two or more of the selected films. In the embodiment, the dielectric film 17 is a single-layer SiO₂ film.

The first electrode 19 is an n-type contact electrode (n-side electrode), and formed on the other surface (rear surface) of the substrate 10. In the embodiment, the first electrode 19 is formed to make contact with and connect to the substrate 10 which is an n-type GaN substrate. The first electrode 19 is a multilayer film formed of three layered metal films each made of Ti/Pt/Au in relation to substrate 10.

The second electrode 20 is a p-type contact electrode (p-side electrode) and formed on the top face of the contact layer of the second conductivity type 16. Preferably, the second electrode 20 is made of a metal which can make excellent contact with the p⁺type GaN layer. The second electrode 20 may be a single layer film made of one of Pd and Ni or a multilayer film formed of layered two or more of the single layer films.

Furthermore, in the embodiment, the width of the second electrode 20 is formed wider than the width of the ridge 15a of the cladding layer of the second conductivity type 15 and the width of the contact layer of the second conductivity type 16. The second electrode 20 has an eave (protruding portion) protruding sideway from the top face of the ridge portion (top face of the contact layer of the second conductivity type 16). It is noted that, in the embodiment, the eave of the second electrode 20 is formed to protrude as far as the thickness of the dielectric film 17 formed on the lower portion of the side surface of the ridge 15a.

The third electrode 21 is a p-side pad electrode, and formed over the top faces of the second electrode 20 and the dielectric film 17 to cover the second electrode 20 and the ridge portion (the ridge 15a and the contact layer of the second conductivity type 16). In the embodiment, the third electrode 21 is continuously formed from the second electrode 20 above the ridge 15a through the dielectric film 17 on the planar portion 15b.

Preferably, the third electrode 21 has (i) excellent adherence to the second electrode 20 or the dielectric film 17, and (ii) a multilayer structure which prevents inter-diffusion of metals. Preferably, the thermal expansion coefficient of the metal of which the third electrode 21 is made is lower than the thermal expansion coefficient of the metal of which the second electrode 20 is made. The third electrode 21 may be made of a metal having a lower thermal expansion coefficient than that of Pd or Ni. For example, the third electrode 21 may be made of a multilayer film formed of three layered metal films each made of Ti/Pt/Au in relation to the second electrode 20. Here, preferably, at least the outermost metal layer in the multilayer film may be continuously formed above the ridge 15a through the planar portion 15b.

In the embodiment, the second electrode 20 has the eave protruding from the ridge portion. Thus, directly below the eave, the cavity 18 is created to be surrounded by (i) a part of the cladding layer of the second conductivity type 15; that is the upper portion of the side surface of the ridge 15a, (ii) the side surface of the contact layer of the second conductivity type 16, and (iii) the inner side surface (the side facing to the ridge portion) of the third electrode 21. Here, the part of the cladding layer of the second conductivity type 15 is formed to be exposed to the dielectric film 17. The cavity 18 is shaped in a stripe along with the stripe direction of the ridge 15a.

In the embodiment, FIG. 1 shows that the second electrode 20 and the third electrode 21 do not make contact with any one of the upper portion of the side surface of the ridge 15a and the side surface of the contact layer of the second conductivity type 16. Here, a region having no contact at least with the ridge 15a of the cladding layer of the second conductivity type 15 may be created within the scope of the present invention. Furthermore, the second electrode 20 is not formed on the dielectric film 17 provided on the side surface of the ridge 15a and on the planar portion 15b; however, the second electrode 20 may be formed on dielectric film 17 as far as the second electrode 20 is spaced apart the eave above the contact layer of the second conductivity type 16. Here, the second electrode 20 is separately formed on the contact layer of the second conductivity type 16 and on the planar portion 15b of the cladding layer of the second conductivity type 15.

It is noted that the above-structured semiconductor laser device 1 according to the embodiment has the resonator length of 800 μm and the chip width of 200 μm, for example.

As described above, in the semiconductor laser device 1 according to the embodiment of the present invention, the lower portion of the side surface of the ridge 15a of the cladding layer of the second conductivity type 15 is connected with the third electrode 21 via the dielectric film 17. This structure makes it possible to efficiently dissipate the heat generated directly below the ridge 15a (directly below the ridge portion) where the highest heat is generated under a high-power operation. In addition, the planar portion 15b of the cladding layer of the second conductivity type 15 is also connected with the third electrode 21 via the dielectric film 17. This structure makes it possible to dissipate the heat generated on the ridge 15a from the planar portion 15b. Thus, the heat dissipation capacity of the ridge 15a (ridge portion) is successfully secured.

In addition, the semiconductor laser device 1 according to the embodiment of the present invention has the cavity 18. Thus, the p-side third electrode 21 is formed not to make contact with a part of the cladding layer of the second conductivity type 15. This structure successfully reduces the compressive strain to be exerted on the active layer 13 even with the use of an electrode material, for the second electrode 20, having a high thermal expansion coefficient.

In the embodiment, moreover, the contact layer of the second conductivity type 16 is formed between the ridge 15a and the second electrode 20. Thus, the cavity 18 is found between the side surface of the contact layer of the second conductivity type 16 and the third electrode 21. Thus, the third electrode 21 is formed not to make contact with the side surface of the contact layer of the second conductivity type 16, either. This structure successfully reduces the compressive strain to be exerted on the active layer 13.

The semiconductor laser device 1 according to the embodiment successfully reduces the compressive strain developed on the active layer even with the use of an electrode material having a high thermal expansion coefficient while securing the heat dissipation capacity of the ridge. This structure allows the lifetime characteristics of the semiconductor laser device.

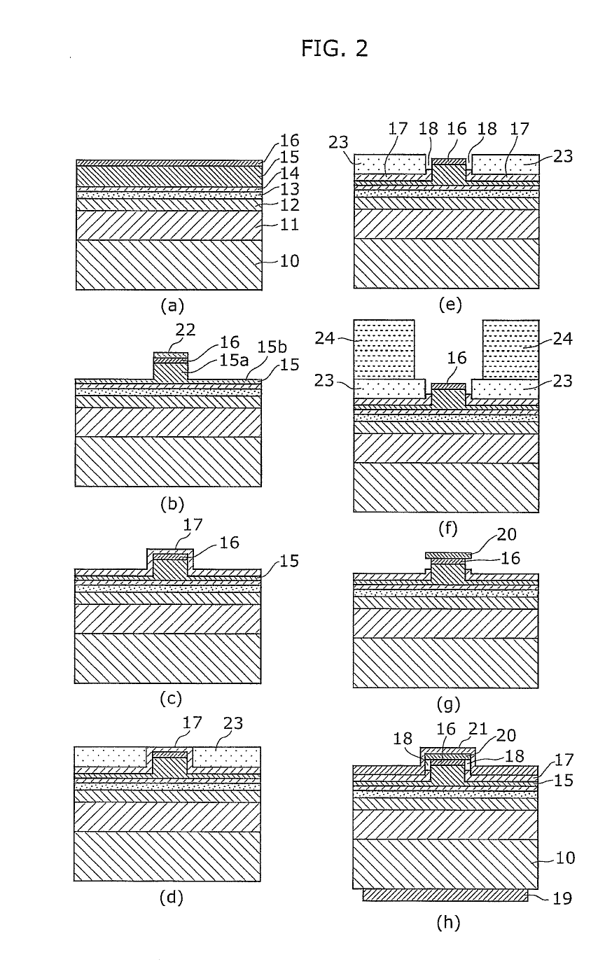

Described next is a method of manufacturing a semiconductor laser device according to the embodiment of the present invention, with reference to FIG. 2. FIG. 2 shows cross-sectional views of each of manufacturing schemes in the method of manufacturing the semiconductor laser device according to the embodiment of the present invention. It is noted that FIG. 2 shows cross-sectional views of a current injection region of a semiconductor laser.

As shown in (a) of FIG. 2, on the substrate 10 which is the n-type GaN substrate, the following layers are sequentially layered to form semiconductor multilayer, using the Metal Organic Chemical Vapor Deposition (MOCVD): the cladding layer of the first conductivity type 11 made of n-type AlₓGa₁₋ₓN (x=0.03); the light guide layer of the first conductivity type 12 which is an n-type Ga light guide layer; the active layer 13 which is a quantum well active layer and formed of a barrier layer made of In_{y}Ga_{1-y}N (y=0.08) and a well layer made of InₛGa₁₋ₛN (s=0.03); the light guide layer of the second conductivity type 14 which is a p-type Ga light guide layer; the cladding layer of the second conductivity type 15 which is a p-type AlₜGa₁₋ₜN (t=0.03); and the contact layer of the second conductivity type 16 which is a p⁺-type GaN contact layer.

Next, as shown in (b) in FIG. 2, a stripe-like mask pattern 22, made of SiO₂ having a desired film thickness, is formed on the contact layer of the second conductivity type 16 on the surface of the semiconductor multilayer The mask pattern is formed by either the dry etching or the wet etching, using a resist pattern. Then, using the mask pattern 22, a part of the cladding layer of the second conductivity type 15 and the contact layer of the second conductivity type 16 are etched, such that a stripe-like ridge portion (the ridge 15a and the contact layer of the second conductivity type 16) is formed. The etching employs the dry etching, using chlorine gas (Cl₂). Then, the mask pattern 22 is removed by the wet etching, using buffered hydrogen fluoride. It is noted that the ridge portion is tapered with its side surface having an inclination angle from 70° to 90°. The bottom (basal surface of the ridge portion) size may be a desired width. It is noted that the ridge portion may be partly inversely tapered near the contact layer of the second conductivity type 16.

Next, as shown in (c) in FIG. 2, the dielectric film 17 made of SiO₂ is formed by the Chemical Vapor Deposition (CVD). Covering the ridge portion, the dielectric film 17 is provided on (i) the exposed regions (top face and side surface) of the contact layer of the second conductivity type 16 and (ii) the exposed regions (all the side surfaces of the ridge 15a and all the surfaces of the planar portion 15b) of the cladding layer of the second conductivity type 15. The dielectric film 17 is used as a current block layer of the semiconductor laser device 1. It is noted that, instead of the CVD, another technique such as the thermal CVD and the plasma CVD may be employed for forming the dielectric film 17. Furthermore, the film thickness of the dielectric film 17 may be approximately 50 nm to 1000 nm. Considering the light confinement effects by the dielectric film 17, the film thickness is preferably 50 nm to 300 nm.

In addition, the dielectric film 17 deposited on the side surface of the ridge portion is preferably shaped by the Reactive Ion Etching (RIE) using inactive gas such as argon. Specifically, the dielectric film 17 is shaped in a tapered mesa having a desired inclination angle from approximately 70° to 85° with respect to a vertical direction. This scheme can prevent disconnection, of the electrode caused by step, developed at the protruding portion of the ridge portion, when forming the third electrode 21.

In the embodiment, SiO₂ is used as a material of the dielectric film 17; instead, AlN or Al₂O₃ may also be used as the material since they are easily etched.

Next, a first resist film 23 is formed on the dielectric film 17. As shown in (d) in FIG. 2, an opening is created on the first resist film 23 such that the top portion of the dielectric film 17 over the ridge portion is exposed. The opening may be created by the resist etchback employing the O₂ plasma treatment, for example.

Then, as shown in (e) in FIG. 2, the dielectric film 17 exposed at the opening of the first resist film 23 is etched by the wet etching using buffered hydrogen fluoride, for example. Here, only the part of the dielectric film 17 making contact with the upper portion of the side surface of the ridge portion is selectively removed, such that exposed is a part of the side surface of the ridge portion.

The embodiment involves exposing the part of the side surface of the ridge portion to form the cavity 18. Thus, the dielectric film 17 is etched such that (i) the part of the dielectric film 17 making contact with the upper portion of the side surface of the ridge portion is removed and (ii) the part of the dielectric film 17 making contact with the lower portion of the side surface of the ridge portion is left to obtain the heat dissipation capability of the base portion of the ridge portion.

More specifically, removed are (i) the dielectric film 17 on the top face (region on which the second electrode 20 is formed) and the side surface of the contact layer of the second conductivity type 16, and (ii) the dielectric film 17 on the upper portion of the side surface of the ridge 15a such that a part of the side surface of the ridge 15a is exposed for a desired height from the dielectric film 17. This etching selectively removes the part of the dielectric film 17 making contact with the upper portion of the side surface of the ridge portion. Accordingly, the dielectric film 17 is left to cover the lower portion (base portion) of the side surface of the ridge 15a and the planar portion 15b.

Next, as shown in (f) of FIG. 2, a second resist film 24 is pattern-formed on the first resist film 23 after the resist etchback. Such a double-layer resist technique makes it possible to selectively and stably form the second electrode 20 on the contact layer of the second conductivity type 16 when lifting off the second electrode 20 described later. In addition, coating a part of the ridge portion with the second resist film 24 can provide a region with no opening on the dielectric film 17. This structure may also be used, for example, as a current injection-free structure near the laser facet.

It is noted that the scheme forming the second resist film 24 is not mandatory. In the case where the double-layer resist technique is to be used, it is preferable to apply the first resist film 23 to the entire surface of the dielectric film 17 such that the first resist film 23 lies flat near the ridge portion, and deactivate the first resist film 23 by heating at 150° C. or higher. Any right deactivation technique, such as the UV curing technique, may be employed.

Next, the second electrode 20; namely the p-type contact electrode, is formed on the entire wafer, using the rotating vapor deposition technique which is one of the rotating film forming techniques (planetary dome type). Then, as shown in (g) in FIG. 2, unnecessary vapor-deposited film on the first resist film 23 and the second resist film 24 is removed by the lifting off, and the second electrode 20 is selectively formed on the contact layer of the second conductivity type 16.

Here, the use of the rotating vapor deposition technique, which can obliquely deposits the evaporated particles, makes it possible to form the second electrode 20 such that the electrode width of the second electrode 20 formed on the contact layer of the second conductivity type 16 is wider than the width of the top face (width of the contact layer of the second conductivity type 16) of the ridge portion, while the rotating vapor deposition technique avoids forming the second electrode 20 on the exposed part of the ridge portion. This technique successfully forms the eave only above the ridge portion, using the second electrode 20. Thus, when the third electrode 21 is deposited in the next scheme, the cavity 18 can be easily and stably formed on the side surface of the ridge portion. The second electrode 20 may also be formed on the dielectric film 17 having an opening by the wet etching.

Here, the second electrode 20 may be formed in a desired film thickness out of a metal to be connected to the contact layer of the second conductivity type 16 with low contact resistance. For example, the second electrode 20 may be a film having (i) a metal including a single layer or metals including two or more layers selected from one of Pd and Ni, and (ii) the topmost surface layer which facilitates the junction with the third electrode 21. In order to obtain stable contact characteristics, moreover, the ohmic annealing is preferably executed after the second electrode 20 is formed.

Then, as shown in (h) in FIG. 2, the third electrode 21 is formed on the second electrode 20, using the revolving vapor deposition technique which is one of the revolving (normal dome type) film-forming techniques. The third electrode 21 is formed on an area wider than the second electrode 20 is, and is used as a pad electrode working as a bond area in a scheme such as the die bonding and the wire bonding. The third electrode 21 is preferably a multilayer film made of Au and having two or more layers which can prevent inter-diffusion of metals. Furthermore, the third electrode 21 is preferably formed in a layered structure made of electrode materials other than Pd and Ni having a great thermal expansion coefficient and a remaining stress. Such a third electrode 21 may be a multilayer film including Ti/Pt/Au, for example.

Here, the revolving vapor deposition technique, which vertically deposits the evaporated particles, is used for forming the third electrode 21. This allows the stripe-like cavity 18 to be stably formed between the third electrode 21 and the side surface to which the ridge portion is exposed, employing the eave formed of the second electrode 20. As far as the third electrode 21 forming the cavity 18, at least the outermost metal layer in the multilayer film may be continuously formed above the ridge portion through a planar portion. The other electrode metal layers may have discontinuous portions on the side surface of the cladding layer of the second conductivity type 15. When the third electrode 21 is a multilayer film including Ti/Pt/Au, for example, the outermost layer Au may be formed continuously.

It is noted that a thick metal is plated as a fourth electrode on the third electrode 21; namely, the pad electrode (not shown). Preferably, a metal is electrically plated, using the third electrode 21 as a power feed film. For example, the continuously formed Au layer as the outermost layer makes the cavity 18 to be stably formed. The metal may be plated by a predetermined plating process.

As described above, the cavity 18 is provided in a stripe-like form between the side surface of the ridge portion and the third electrode 21. This cavity 18 produces a buffering effect to successfully alleviate the stress to be imposed on the active layer 13 by the electrode.

Finally, the substrate 10 is ground and polished in a desired thickness (100 μm), and the first electrode is formed to make contact with and connect to the rear surface of the substrate 10. Hence, the GaN semiconductor laser diode as shown in FIG. 1 is manufactured.

Then, though not shown, the GaN semiconductor laser diode is cleaved in a bar. Then, the laser facet of the semiconductor is coated with a dielectric film to have a desired reflection rate. Finally, the semiconductor is divided into chips.

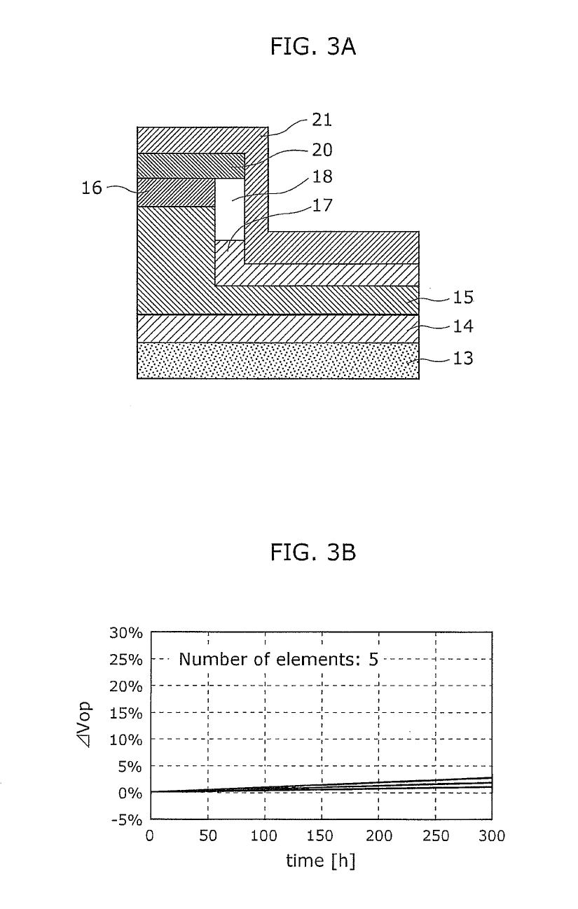

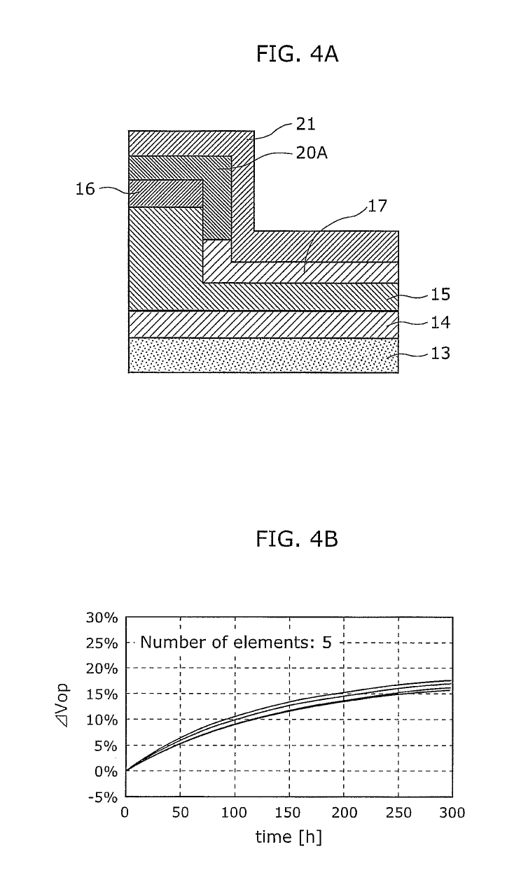

Described next is an experiment in lifetime characteristics of the semiconductor laser device according to the embodiment of the present invention, with reference to FIGS. 3A to 4B.

FIG. 3A shows a cross-sectional view of an enlarged substantial part of the semiconductor laser device according to the embodiment of the present invention. FIG. 3B depicts a relationship between the time change and the operating voltage change observed in the semiconductor laser device according to the embodiment of the present invention. It is noted that FIG. 3A is an enlarged view of a surrounding area of the cavity 18. The same constitutional elements as FIG. 1 share the same numerical references. FIG. 3B shows test time dependency of the variation in an operating voltage (Vop) value. FIG. 3B shows the result of a current test under a certain amount of optical output after the semiconductor laser device chip manufactured by the above method is die-bonded on a heatsink. In the embodiment, five semiconductor laser devices each were prepared, and the variation of the operational voltage (Vop) was measured when the five semiconductor laser devices were continuously oscillated for 300 hours.

Furthermore, FIG. 4A shows a cross-sectional view of an enlarged substantial part of a semiconductor laser device according to a comparative example. FIG. 4B depicts a relationship between the time change and the operating voltage change observed in the semiconductor laser device according to the comparative example. It is noted that the structure in FIG. 4A shows the cavity 18 in FIG. 3A filled with a second electrode 20A. In order to obtain the structure, the second electrode is deposited by the revolving (normal dome type) film-forming technique. Moreover, the result of FIG. 4B is measured by the same technique as the result of 3B.

First, in FIG. 3B, the semiconductor laser device according to the embodiment showed that the percentage of rise in the voltage was between 2% to 3% even though the semiconductor laser devices were conducting a current for 300 hours, and the operation voltage was measured in the 300 hours. Thus, the semiconductor laser devices according to the embodiment were able to obtain a stable operation voltage for a long period of time, and showed excellent lifetime characteristics.

In contrast, the semiconductor laser device according to the comparative example in FIG. 4B showed that the operation voltage rose as time passed while the semiconductor laser devices were conducting a current for 300 hours. In 300 hours, the percentage of rise in the voltage was equal to or greater than 16%. Thus, the semiconductor laser devices failed to obtain excellent lifetime characteristics.

As shown above, the semiconductor laser device according to the embodiment has the stripe-like cavity 18 provided between (i) the side surface of the ridge 15a of the cladding layer of the second conductivity type 15; namely a p-type cladding layer, and (ii) the third electrode 21; namely a pad electrode. This cavity 18 can generate a stress in the same direction as the tensile strain to be developed on the cladding layer of the second conductivity type 15, while securing the heat dissipation capacity of the side surface of the ridge 15a and the base portion of the ridge portion. This structure successfully reduces the compressive strain to be exerted on the active layer 13 even with the use of an electrode material having a high thermal expansion coefficient for the third electrode 21. This leads to an improvement in lifetime characteristics of the semiconductor laser device.

Although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

### INDUSTRIAL APPLICABILITY

The present invention is useful as a semiconductor laser device to be employed for a optical pickup device in an optical disc system.

What is claimed is:

1. A semiconductor laser device comprising:
a substrate;
a cladding layer of a first conductivity type formed above one of surfaces of said substrate;
an active layer formed above said cladding layer of the first conductivity type;
a cladding layer of a second conductivity type formed above said active layer, and having a ridge and a planar portion provided on a surface of said cladding layer of the second conductivity type;
a dielectric film formed on a lower portion of a side surface of said ridge and on said planar portion;
a first electrode formed on an other one of the surfaces of said substrate;
a second electrode formed above said ridge;
a third electrode formed over said second electrode and said dielectric film to cover said ridge and said planar portion; and
a cavity provided between said third electrode and at least a part of the side surface of said ridge.

2. The semiconductor laser device according to claim 1, further comprising
a contact layer of the second conductivity type formed between said second electrode and said ridge of said cladding layer of the second conductivity type,
wherein said cavity is provided between said third electrode and the side surface of said contact layer of the second conductivity type.

3. The semiconductor laser device according to claim 1 made of a III-V group nitride semiconductor material in an InAlGaN series.

4. The semiconductor laser device according to claim 3,
wherein said cladding layer of the second conductivity type is made of AlGaN.

5. The semiconductor laser device according to claim 3,
wherein said active layer is made of InGaN.

6. The semiconductor laser device according to claim 1,
wherein said second electrode is one of (i) a single layer film made of Pd or Ni and (ii) a multilayer film made of Pd and Ni.

7. The semiconductor laser device according to claim 1,
wherein said third electrode is a multilayer film made of metals other than Pd and Ni, and
at least an outermost metal layer of the multilayer film is formed continuously above said ridge through said dielectric film.

8. The semiconductor laser device according to claim 1,
wherein said dielectric film is one of (i) a single layer film, such as a SiO₂ film, an AlN film, or an Al₂O₃ film and (ii) a multilayer film including at least two of the SiO₂ film, the AlN film, and the an Al₂O₃ film.

9. The semiconductor laser device according to claim 1,
wherein said second electrode is wider than said ridge.

10. A method for manufacturing a semiconductor laser device, comprising:
sequentially forming, on a substrate, a cladding layer of a first conductivity type, an active layer, a cladding layer of a second conductivity type, and a contact layer of the second conductivity type;
forming a ridge portion by etching the cladding layer of the second conductivity type and the contact layer of the second conductivity type;
forming a dielectric film to cover the ridge portion;
etching the dielectric film to selectively expose a side surface of the ridge portion;
forming a second electrode above the ridge portion; and
forming a third electrode over the second electrode,
wherein, in said forming the second electrode, the second electrode is (i) formed by a rotating film-forming technique on the contact layer of the second conductivity type but not on the exposed side surface of the ridge portion, and (ii) formed wider than a top face of the contact layer of the second conductivity type, and
in said forming the third electrode, the third electrode is formed by a revolving film-forming technique such that a cavity is provided between the third electrode and the exposed side surface of the ridge portion.
